(19) United States
(12) Patent Application Publication
(10) Pub. No.: US 2019/0138097 A1
(43) Pub. Date: May 9, 2019

(54) OPERATING DEVICE, IN PARTICULAR IN THE FORM OF A TOUCHPAD

(71) Applicant: Marquardt GmbH, Rietheim-Weilheim (DE)

(72) Inventors: Vinko SCHOSSAU, Radolfzell (DE); Benjamin Schaefer, Sulz am Neckar (DE); Dieter Hartmann, Uberlingen (DE); Joerg Reisinger, Lochgau (DE); Jochen Sendler, Stuttgart (DE)

(73) Assignee: Marquardt GmbH, Rietheim-Weilheim (DE)

(21) Appl. No.: 16/180,343

(22) Filed: Nov. 5, 2018

Related U.S. Application Data
(63) Continuation of application No. PCT/EP2017/060734, filed on May 5, 2017.

(30) Foreign Application Priority Data
May 6, 2016 (DE) 10 2016 005 427.1

(51) Int. Cl. G06F 3/01; H03K 17/96; G06F 3/0354

(52) U.S. Cl. CPC G06F 3/016; H03K 17/96; H03K 2217/96038; H03K 2217/96062; G06F 3/03547

(57) ABSTRACT

An operator control apparatus, in particular for a motor vehicle, having an operating surface for manual action by an element, particularly the finger of a human hand. A sensor interacts with the operating surface such that the sensor generates a signal when the element approaches the operating surface and/or when the operating surface is touched by the element and/or when pressure is applied to the operating surface by the element. The signal is used for switching and/or triggering a function in the style of a switching signal. The actuator is operatively connected to the operating surface, such that a haptic event is producible for the operating surface by means of actuation of the actuator. The actuator is driven electrically and operable by a PWM (pulse width modulation) actuation signal, such that the operating surface is movable in a preselectable manner within a preselectable displacement and/or time.

This application is a continuation of International Application No. PCT/EP2017/060734 filed May 5, 2017, which designated the United States, and claims the benefit under 35 USC § 119(a)-(d) of German Application No. 10 2016 005 427.1 filed May 6, 2016, 2015, the entireties of which are incorporated herein by reference.

### FIELD OF THE INVENTION

The present invention relates to an operator control apparatus.

### BACKGROUND OF THE INVENTION

An operator control apparatus of this kind can be used as a touch pad, for example, in particular, in a motor vehicle. As such, an operator control apparatus of this kind may be arranged in the central console of a motor vehicle, for example, and can be used for controlling a screen in the motor vehicle. An operator control apparatus of this kind can also be used as a part of a screen in the style of a touchscreen.

An operator control apparatus of this kind has an operating surface for manual action by means of an element. The element may be the finger of a human hand, so as to control a cursor on the screen, for example, as a result of appropriate action on the operating surface by means of the finger of the user. The element may also be a stylus, however. A sensor interacts with the operating surface such that the sensor generates a signal when the element approaches the operating surface and/or when the operating surface is touched by means of the element and/or when pressure is applied to the operating surface by means of the element. The signal is then used for switching and/or triggering a function in the style of a switching signal. Additionally, an actuator is operatively connected to the operating surface, such that the operating surface is movable by operation of the actuator so as to produce a haptic sense for the operating surface. In other words, a tactile haptic sense is producible for the operating surface by means of actuation of the actuator, in order thereby to provide the user with palpable feedback for his action on the operating surface.

However, this involves a simple movement of the operating surface, which means that the previous palpable feedback is often criticized by the user as inadequate. Moreover, the actuator is actuated with a square-wave signal or with a change-change signal in the style of an on/off switching process, for example, just to prompt a vibration for the operating surface, which, following termination of the actuation, settles and decays freely in accordance with its fixed spring-mass-damper system. If required, discrete mechanical, hydraulic or the like vibration dampers can then additionally be used for damping the decay behavior of the vibration, this firstly not being very flexible and secondly giving rise to increased costs.

### SUMMARY OF THE INVENTION

The present invention is based on the object of developing the operator control apparatus further such that the diversity for the haptic sense is increased and/or the functionality for the haptic sense is improved.

In the operator control apparatus according to the present invention, the actuator is driven electrically. The actuator is operable by means of a PWM (pulse width modulation) actuation signal, such that the operating surface is movable in a preselectable manner. In particular, this means that the operating surface is movable within a preselectable displacement and/or a preselectable time and/or preselectable pattern. Advantageously, using an appropriately chosen shape and/or style for the PWM actuation signal, the tactile haptic sense respectively desired by the user is producible for the operating surface in a simple manner. The multiplicity of producible different haptic senses mean that the user can be provided with specific feedback according to the respective control of the operator control apparatus.

In a simple configuration, the electrically driven actuator may be an electromagnet, an electric motor, a piezo element or the like. If an electrode magnet is used as the actuator, then it is possible to use a solenoid therefor, as a result of which a particularly compact configuration of the operator control apparatus is attainable.

The actuator is used, as already mentioned, for appropriately moving the operating surface. If desired, the actuator can alternatively and/or additionally be used for slowing down the movement of the operating surface. In this case, the actuator is operatable by means of the PWM actuation signal so as to preselectably damp the movement of the operating surface. By way of example, this provides a simple way of preventing undesirable post-impulse oscillation of the operating surface at the conclusion of the haptic output.

For a tactile haptic sense that the user perceives as particularly ergonomic, the signal shape of the PWM actuation signal can comprise a frequency modulation with decaying signal strength. To produce the preselected movement for the operating surface in a simple manner, the parameters of the PWM actuation signal, in particular the starting frequency, end frequency, intensity profile, modulation signal shape, or the like, thereof, may be variable. In order to produce a particularly prominent haptic sense, it is possible for at least two PWM actuation signals, in particular in the form of frequency-modulated actuation signals, to be overlaid on one another. As a result, portions of the movement of the operating surface such as the initial impulse, period of vibration, vibration damping or the like, thereof, may be boosted and/or attenuated.

In a simple and inexpensive configuration, the actuator may be electrically connected by means of a switching transistor to a voltage source for operating the actuator. In addition, a control circuit in the style of a controller may be provided for actuating the switching transistor by means of the PWM actuation signal. This advantageously provides electrically simple, operationally reliable and inexpensive PWM actuation for the actuator and/or the switching transistor.

The present invention additionally provides a method for operating an operator control apparatus, in particular, one suitable for a motor vehicle. The operator control apparatus has an operating surface for manual action by means of an element, wherein, in particular, the element is the finger of a human hand, and a sensor interacting with the operating surface, such that the sensor generates a signal used for switching and/or triggering a function, in particular in the style of a switching signal, when the element approaches the operating surface and/or when the operating surface is touched by means of the element and/or when pressure is applied to the operating surface by means of the element. An electrically driven actuator is operatively connected to the operating surface, such that the operating surface is moved by operation of the actuator so as to produce a haptic sense for the operating surface. In other words, a tactile haptic sense is produced for the operating surface by means of actuation of the actuator. The actuator is operated, according to the present invention, by means of an actuation signal, which is different than a change-change signal in the style of a switching-on and/or switching-off process. Preferably, this actuation signal different than a change-change signal is a PWM (pulse width modulation) signal, which means that the actuator is operated by means of a PWM (pulse width modulation) signal. Specifically, it is operated such that the operating surface moves in a preselectable manner, in particular, within a preselectable displacement and/or a preselectable time and/or a preselectable pattern.

In a further configuration of the method for operating the operator control apparatus, the actuator can be operated by means of the PWM actuation signal such that the operating surface is moved in preselectably damped fashion. Undesirable post-impulse oscillation of the operating surface following the tactile feedback thereof can thus be prevented effectively. In addition, the parameters for the PWM actuation signal, in particular, the starting frequency, end frequency, intensity profile, modulation signal shape, or the like, thereof, can be adjusted such that the preselected movement of the operating surface is produced. Finally, at least two PWM actuation signals, in particular in the form of frequency-modulated actuation signals, can be overlaid on one another. As a result, it is a simple matter for portions of the movement of the operating surface, such as the initial impulse, period of vibration, vibration damping, or the like, thereof, to be boosted and/or attenuated.

For a particularly preferred configuration of the operator control apparatus according to the present invention, the following can be established.

The operating surface, for example, corresponding to the function of a computer mousepad, of an operator control assembly needs to be provided with an active haptic sense in order to be able to convey different kinds of haptic events to the user. The system with active haptic feedback is supposed to provide the most impulse-faithful reproduction of the haptic feedback possible, which is supposed to come close to a mechanical switch, for example. The active haptic sense is produced by an electrically driven actuator whose deflection is controllable electrically, for example, in the specific case a solenoid. Therefore, the actuation of an electrically driven actuator is provided to produce haptic events.

The aim of the different kinds of haptic events is, inter alia, to provide the user with tactile feedback. By way of example, this feedback can result in the user having the impression conveyed to him that he is operating mechanical operator control elements, such as operating a conventional short-stroke key or rotating a computer mouse wheel with latching changes, for example.

Depending on the desired effect, this requires the operating surface to be moved in a quite particular manner within a particular time and/or a particular displacement. The challenge in this case is to greatly speed up and bring to rest again the operating surface as an assembly of prescribed mechanical design with its specific property as a spring-mass-damper system in a very short time. Variations are meant to be possible in this case in order to depict different patterns of movement.

In order to produce the different demanded patterns of movement to be generated in the same device in optimum fashion, simple electrical actuation signals with a mechanical and/or other discrete damper for vibration damping would not suffice. To produce the respective pattern of movement for the operating surface in optimum fashion, the actuation of the actuator can thus also be jointly used to produce the damping. In particular, the mechanical vibrations can be damped effectively by means of appropriate actuation signal shapes for actuating the actuator in phase opposition. As such, the optimum damping in each case can be produced for each pattern of movement.

The actuator is actuated with different PWM signals. In an extension, the solution according to the present invention is the particular shaping of the PWM signals, in particular, by virtue of the signal shape of the actuator actuation signal corresponding to a frequency modulation with decaying signal strength. The stimulation with a frequency-modulated and/or damped harmonic vibration matched to the natural-frequency vibration allows the mass of the haptic system to be greatly speeded up and/or subsequently greatly damped. All of the parameters of the actuation signal, in particular the starting frequency, the end frequency, the intensity profile, the modulation signal shape, or the like, can be changed or varied to depict the desired pattern of movement of the operating surface. For the purpose of interpreting the haptic effect in optimum fashion and/or as desired, in particular, the following optimization parameters for the actuation signal are therefore available:
intensity,
damping,
starting frequency,
target frequency, and
frequency profile.

In order to boost part-properties, for example, the initial impulse, the period of vibration of the driven system, the vibration damping, or the like, in a specific manner, two and/or more of these frequency -modulated signals can be overlaid on one another.

The advantages attained by means of the present invention are, in particular, the following:
No mechanical damping is required for the operating surface.
A few parameters can be used to select diverse haptic effect.
There is a good opportunity for monitoring the haptic s effect.
It is possible to use electrically simple and high-efficiency PWM actuation using a switching transistor.
The frequency-modulated actuator actuation signal according to the present invention can act directly as an adjustable active vibration damper on the basis of its frequency-modulated actuation signal shape.
The actuation signal according to the present invention provides new opportunities for shaping the pattern of movement of the operating surface that were not possible previously.
Different haptic effect, for example, for simulating what is known as “force feedback”, as are already known from gaming consoles, can be produced in a single operator control apparatus alone, using the actuation signal shape, in far more differentiated fashion than is possible using previous actuation signals.
The solution according to the present invention is inexpensive, in particular, because it is implementable by means of a purely electronic software solution.

### BRIEF DESCRIPTION OF THE DRAWINGS

An exemplary embodiment of the present invention with different developments and configurations is depicted in the drawings and is described in more detail below.

FIG. 1 shows a perspective view of an operator control apparatus comprising an operating surface and an actuator;

FIG. 2 shows a section along the line 2-2 in FIG. 1;

FIG. 3 schematically shows a circuit diagram for the activation of the actuator;

FIG. 4a shows conventional actuation for the actuator (prior art);

FIG. 4b shows a time-displacement graph for the operating surface when the actuator is actuated as shown in FIG. 4a;

FIG. 5a shows a control signal caused by a PWM actuation signal for the actuator;

FIG. 5b shows a time-displacement graph for the operating surface when the actuator is operated with the control signal as shown in FIG. 5a;

FIGS. 6 to 8 show control signals for the actuator that have different parameters chosen for them;

FIG. 9 shows a PWM actuation signal with a constant DC component; and

FIG. 10 shows a PWM actuation signal with a DC component in the form of a cosine function.

### DETAILED DESCRIPTION OF THE INVENTION

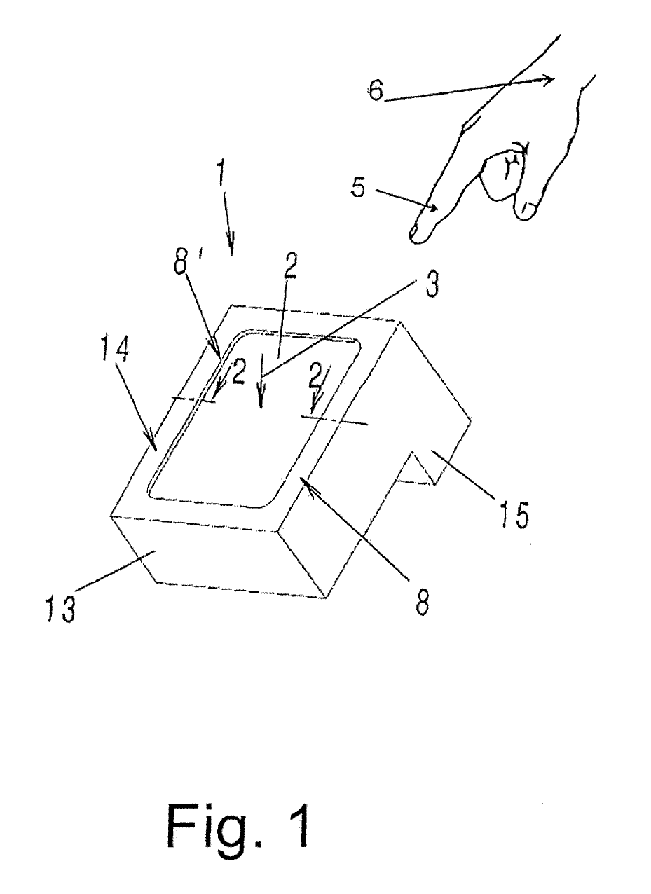

In FIG. 1, it is possible to see an operator control apparatus 1 in the style of a touchpad, which is used, in particular, for a motor vehicle. The operator control apparatus 1 has a housing 13, the manually accessible surface 14 of which has an operating surface 2 on it. The user can control the operator control apparatus 1 in accordance with the requirements by means of manual action on the operating surface 2 by means of an element 5. The element 5 may be the finger 5 of a human hand 6, which means that the control in accordance with requirements is made possible by means of appropriate movement of the finger 5. By way of example, the operator control apparatus 1 may be arranged in the central console of the motor vehicle and may be provided for controlling a navigation system, a screen, or the like, in the motor vehicle. The operator control apparatus 1 is connectable to a bus system in the motor vehicle, for example, by means of a plug connection 15.

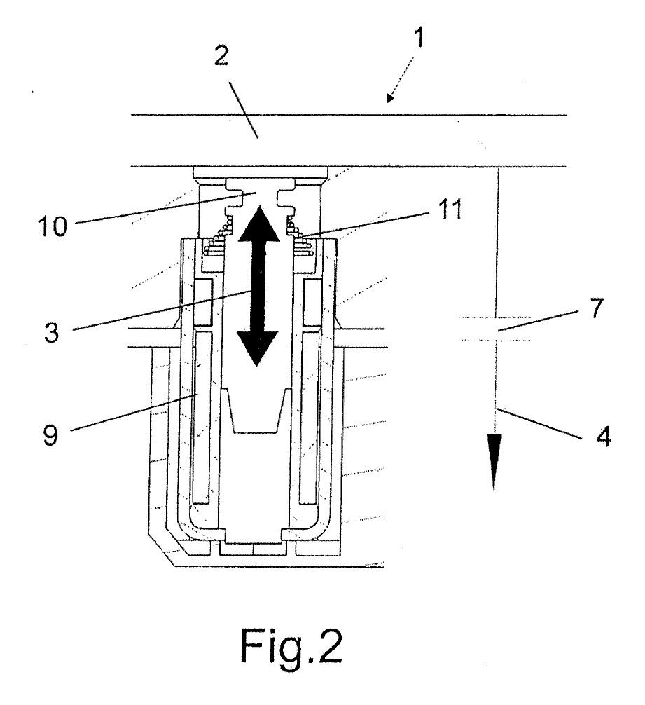

The operator control apparatus 1 is provided with a sensor 7 interacting with the operating surface 2, as can be seen in FIG. 2. The sensor 7 shown in FIG. 2 by way of example and merely schematically is a capacitively operating sensor. Naturally, the sensor 7 can also operate by means of infrared radiation, by means of the Hall effect or by means of other sensor principles. When the element 5, in this case the finger 5 of the hand 6 of the user, for example, approaches the operating surface 2 and/or when the operating surface 2 is touched by means of the element 5 and/or when pressure is applied to the operating surface 2 by means of the element 5, the sensor 7 generates a signal 4 that is forwarded to a controller in the motor vehicle via the plug connection 15. The signal 4 is then used for switching and/or triggering and/or selecting a function in the motor vehicle, for example, in the style of a switching signal.

The operating surface 2 of the operator control apparatus 1 is mounted in the housing 13 so as to be movable in direction 3. For this purpose, according to FIG. 1, the operating surface 2 is configured with a slight gap 8′ from the surrounding edge region 8 of the housing 13. As can further be seen in FIG. 2, an electrically driven actuator 9 is operatively connected to the operating surface 2, such that the operating surface 2 is movable by means of the actuator 9 in accordance with the direction arrow 3. As a result of appropriate actuation of the actuator 9, a tactile haptic sense is then producible for the operating surface 2 by virtue of the operating surface 2 being moved as appropriate by operation of the actuator 9. In the present case, the electrically driven actuator 9 is an electromagnet, specifically a solenoid, which has an armature 10, provided with a return spring 11, that acts on the operating surface 2. Instead of an electromagnet 9, it is also possible for an electric motor, a piezo element, or the like, to be used as the actuator.

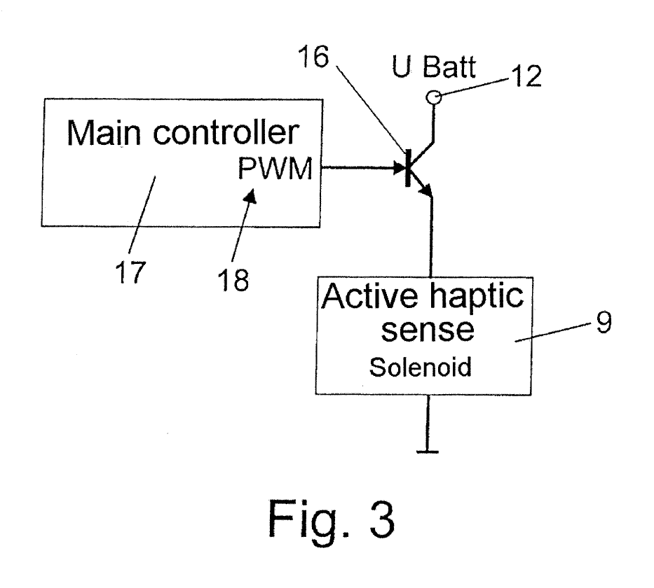

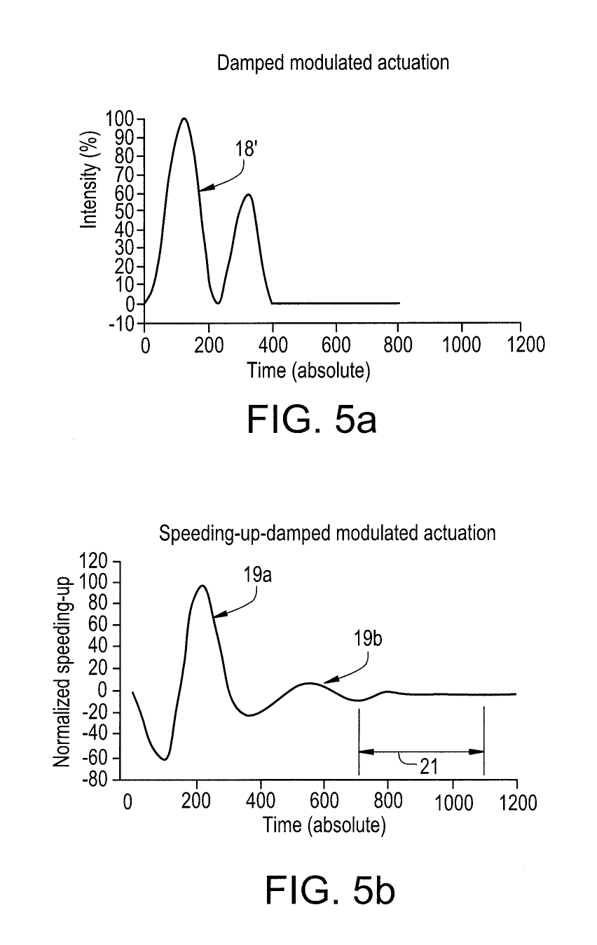

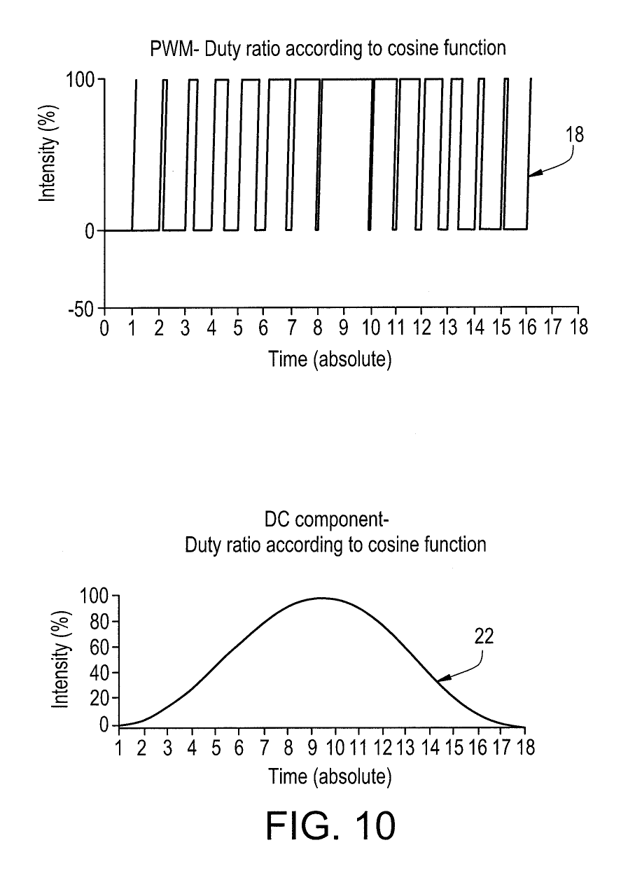

The actuator 9 is operable by means of an actuation signal that is different than a change-change signal, the actuation signal advantageously and also preferably being an electrical PWM (pulse width modulation) actuation signal 18 (for example, see FIG. 10). In this regard, the actuator 9 is electrically connected by means of a switching transistor 16 to an electrical voltage source 12 provided for operating the actuator 9, as can be seen in FIG. 3. Additionally, a control circuit 17 in the style of a controller for actuating the switching transistor 16 by means of the PWM actuation signal 18 is provided, which means that a control signal 18′ (for example, see FIG. 5a) corresponding to the PWM actuation signal 18 acts on the actuator 9 or on the coil of the electromagnet 9. This in turn moves the armature 10 and, with the latter, the operating surface 2 corresponding to the PWM actuator signal 18 or to the control signal 18′ caused by the PWM actuation signal 18 (for example, see FIG. 5b, which depicts the resultant speeding-up of the operating surface 2). Specifically, the operating surface 2 is movable by means of the appropriately chosen PWM actuation signal 18 in a preselectable manner, in particular, within a preselectable displacement and/or a preselectable time and/or a preselectable pattern in the style of a pattern of movement. In addition, the actuator 9 can also be operated by means of the PWM actuation signal 18 such that an appropriately preselectable damping for the movement of the operating surface 2 is attainable.

FIG. 5a depicts, by way of example, a control signal 18′ whose signal shape comprises a frequency modulation with decaying signal strength. Specifically, by way of example, the control signal 18′ shows FM (frequency modulation) actuation with a drop from 100 Hz to 90 Hz, that is to say a liner modulation from a starting frequency to a target frequency. As can further be seen in FIG. 5b, which depicts the resultant speeding -up of the operating surface 2, the operating surface 2 moves in accordance with two movement pulses 19a, 19b in this case. No post-impulse oscillation of the operating surface 2 subsequently occurs in this case, as can be seen from the further movement profile 21.

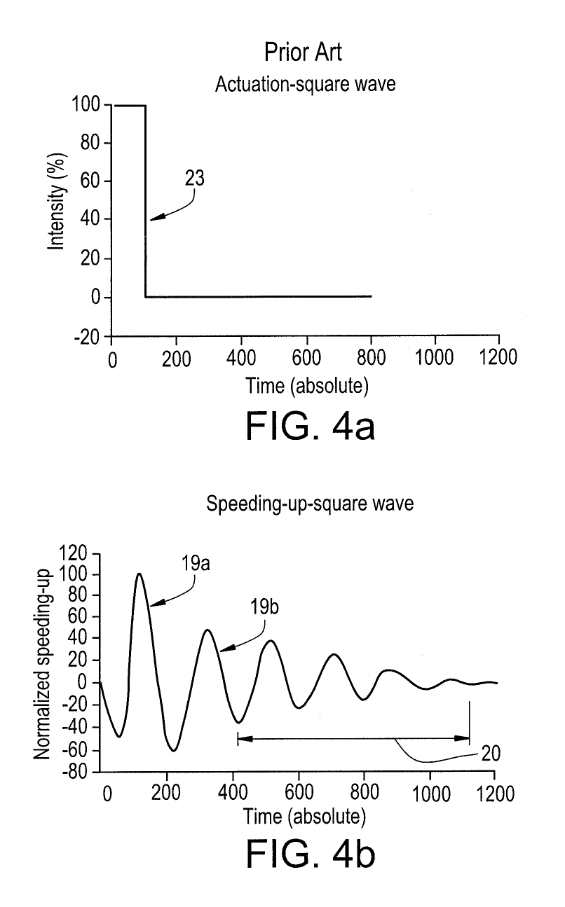

By contrast, the previous actuation of the actuator 9, as a result of simple switching-on and switching-off of the electrical supply voltage thereof or of the coil current for the electromagnet 9, that is to say in accordance with a change-change signal 23 or a square-wave signal 23 as shown in FIG. 4a, wherein the maximum possible energy is supplied to the actuator 9, shows a long post-impulse oscillation 20 following the two movement impulses 19a, 19b, as can be seen in FIG. 4b. A disadvantage that can be established in this case is that a broad uncontrolled frequency spectrum and uncontrolled transient response (frequency and damping) of the haptic system, comprising the operating surface 2 and the actuator 9, is prompted. This haptic system settles in uncontrolled fashion, which is undesirable and, in the worst case, leads to vibrations and background noise. The damping of this conventional haptic system is thus based purely on the mechanical design thereof.

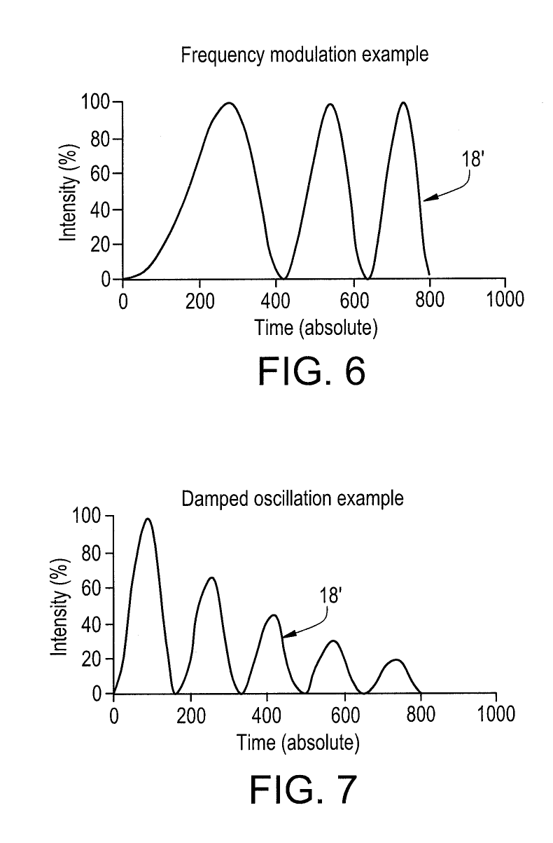

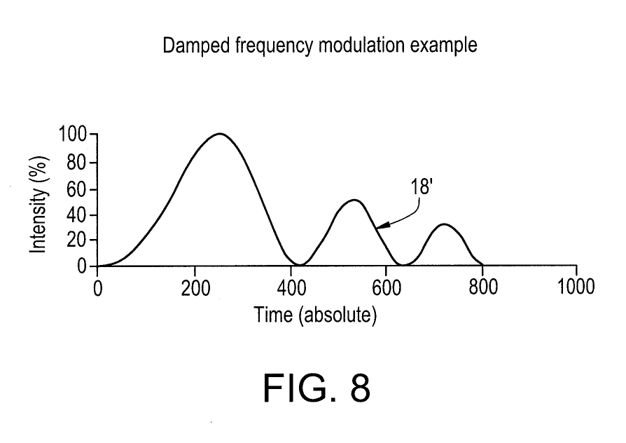

To produce the respective preselected movement for the operating surface 2, the parameters of the control signal 18′ or of the PWM actuation signal 18 can be varied as appropriate. These parameters are, in particular, the starting frequency, the end frequency, the intensity profile, the modulation signal shape, or the like, of the control signal 18′ or of the PWM actuation signal 18. Examples of control signals 18′ of this kind can be seen in FIGS. 6 to 8. As such, FIG. 6 shows a control signal 18′ with frequency modulation, specifically with a linear modulation from a starting frequency to a target frequency. FIG. 7 depicts a control signal 18′ in the style of a damped vibration with non-frequency-modulated actuation and exponential damping. In this case, a higher starting frequency is chosen than the one shown in FIG. 6. In FIG. 8, a control signal 18′ in the style of a damped frequency modulation can be seen, the control signal 18′ consisting of the combination of frequency-modulated actuation with exponential damping. The starting and target frequencies in this case are consistent with the parameters from FIG. 6.

Appropriately combined and optimized parameters allow the mass of the haptic system, comprising the operating surface 2 and the actuator 9, to be speeded up in optimum fashion and subsequently quickly brought to rest again, with vibrations and post-impulse oscillations being suppressed. By way of example, a control signal 18′ of this kind can consist of damped and frequency -modulated actuation. Finally, it is also possible for two and/or more control signals 18′ or PWM actuation signals 18, specifically in particular frequency -modulated actuation signals, to be overlaid on one another. This allows portions of the movement of the operating surface 2, such as the initial impulse, period of vibration, vibration damping, or the like, to be boosted and/or attenuated in specific fashion.

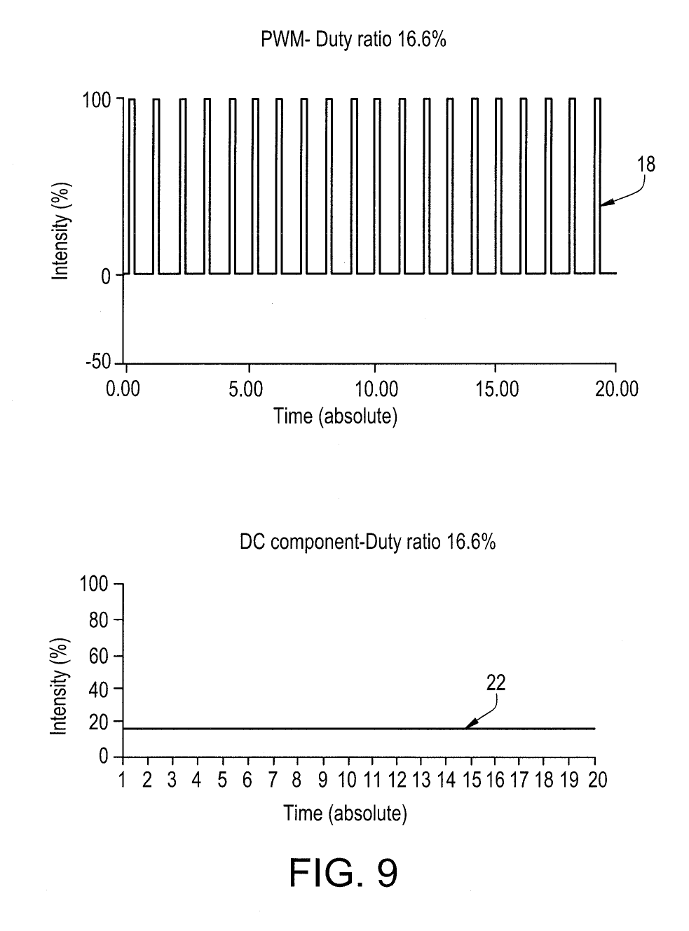

The PWM actuation signal 18 for generating the control signal 18′ causes variable-intensity actuation for the coil of the electromagnet 9, the intensity being controlled by the duty ratio of the PWM signal 18. The coil of the electromagnet 9 forms a low-pass filter that smooths the PWM signal 18, so that an appropriate DC component 22 is obtained, the DC component 22 in turn serving as a control signal 18′ for operating the electromagnet 9. An example of such a PWM signal 18 with a DC converter 22 after the low-pass filtering is shown in FIG. 9. This is a PWM signal 18 with a duty ratio of 16.6%, resulting in a DC component 22 that is constant over time and has an intensity of 16.6% for actuating the actuator 9. In FIG. 10, as a further example, it is possible to see a PWM signal 18 with a duty ratio distribution in the form of a cosine function. This produces a DC component 22 as control signal 18′ for actuating the actuator 9 with an intensity that has the shape of a cosine function over time. The temporal sequence of movement of the operating surface 2 coupled to the actuator 9 in turn corresponds to the intensity profile of the DC component 22 and/or to the frequency modulation.

In summary, it can therefore be established that the operator control apparatus 1 is operated as follows. The actuator 9 operatively connected to the operating surface 2 is driven electrically. In addition, the actuator 9 is operated by means of an actuation signal that is different from a step-change or square-wave signal 23, in particular by means of a PWM (pulse width modulation) actuation signal 18, such that the operating surface 2 moves in a preselectable manner, in particular within a preselectable displacement and/or a preselectable time and/or a preselectable pattern of movement, so as to produce a tactile haptic sense for the operating surface 2.

The present invention is not restricted to the exemplary embodiments described and depicted. Rather, it also comprises all developments familiar to a person skilled in the art within the framework of the invention defined by the patent claims. As such, the operator control apparatus 1 according to the present invention can be used not only as a touch pad for motor vehicles but also as a pad and/or screen in computers and also in domestic appliances, audio appliances, video appliances, telecommunication devices, games consoles, or the like.

### LIST OF REFERENCE SIGNS

1: Operator control apparatus
2: Operating surface
3: Direction/direction arrow
4: Signal
5: Element/finger
6: Hand
7: Sensor
8: Edge region
8′: Gap
9: Actuator/electromagnet
10: Armature (of electromagnet)
11: Return spring (of electromagnet)
12: Voltage source
13: Housing (of operator control apparatus)
14: Surface (of housing)
15: Plug connection (on the housing)
16: Switching transistor
17: Control circuit
18′: Control signal
19a,b: Movement impulse
20: Post-impulse oscillation (prior art)
21: Movement profile
22: DC component (of PWM signal)
23: Change-change signal/square-wave signal (prior art)

1. An operator control apparatus having an operating surface for manual action by means of an element, having a sensor interacting with the operating surface such that the sensor generates a signal when the element approaches the operating surface and/or when the operating surface is touched by the element and/or when pressure is applied to the operating surface by the element, wherein the signal is used for switching and/or triggering a function, and wherein an actuator is operatively connected to the operating surface, such that the operating surface is movable by operation of the actuator so as to produce a haptic event for the operating surface, wherein the actuator is driven electrically, and wherein the actuator is operable by a PWM (pulse width modulation) actuation signal, such that the operating surface is movable in a preselectable displacement and/or a preselectable time and/or a preselectable pattern.

2. The operator control apparatus as claimed in claim 1, wherein the electrically driven actuator is an electromagnet, an electric motor, or a piezo element.

3. The operator control apparatus as claimed in claim 1, wherein the actuator is operable by means of the PWM actuation signal to preselectably damp the movement of the operating surface.

4. The operator control apparatus as claimed in claim 1, wherein the signal shape of the PWM actuation signal comprises a frequency modulation with decaying signal strength.

5. The operator control apparatus as claimed in claim 1, wherein the starting frequency, end frequency, intensity profile, and/or modulation signal shape of the PWM actuation signal, are variable to produce the preselected movement of the operating surface.

6. The operator control apparatus as claimed in claim 1, wherein at least two frequency-modulated actuation signals are overlaid on one another, such that portions of the movement of the operating surface, such as the initial impulse, period of vibration, and/or vibration damping, are boosted and/or attenuated.

7. The operator control apparatus as claimed in claim 1, wherein the actuator is electrically connected by a switching transistor to a voltage source for operating the actuator, and wherein preferably a control circuit in the style of a controller is provided for actuating the switching transistor by the PWM actuation signal.

8. A method for operating an operator control apparatus having an operating surface for manual action by means of an element, having a sensor interacting with the operating surface such that the sensor generates a signal when the element approaches the operating surface and/or when the operating surface is touched by the element and/or when pressure is applied to the operating surface by the element, wherein the signal is used for switching and/or triggering a function, and wherein an actuator is operatively connected to the operating surface, such that the operating surface is moved by operation of the actuator so as to produce a haptic sense for the operating surface, wherein the actuator is driven electrically, and wherein the actuator is operated by means of an actuation signal that is different than a change-change signal, in particular by means of a PWM (pulse width modulation) actuation signal, such that the operating surface moves within a preselectable displacement and/or a preselectable time and/or a preselectable pattern.

9. The method for operating an operator control apparatus as claimed in claim 8, wherein the actuator is operated by means of the PWM actuation signal such that the operating surface is moved in preselectably damped fashion.

10. The method for operating an operator control apparatus as claimed in claim 8, wherein the starting frequency, end frequency, intensity profile, and/or modulation signal shape of the PWM actuation signal, are adjusted such that the preselected movement of the operating surface is produced, and wherein at least two PWM actuation signals, in the form of frequency-modulated actuation signals are overlaid on one another, such that portions of the movement of the operating surface, such as the initial impulse, period of vibration, and/or vibration damping, are boosted and/or attenuated.
